(19) United States
(12) Patent Application Publication
(10) Pub. No.: US 2006/0065622 A1
(43) Pub. Date: Mar. 30, 2006

(54) Method and system for xenon fluoride etching with enhanced efficiency

(76) Inventors: Philip D. Floyd, Redwood City, CA (US); William J. Cummings, San Francisco, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/083,030

(22) Filed: Mar. 17, 2005

Related U.S. Application Data
(60) Provisional application No. 60/613,423, filed on Sep. 27, 2004.

(51) Int. Cl. C23F 1/00; C03C 25/68; B44C 1/22; H01L 21/306

(52) U.S. Cl. 216/58; 216/2; 216/74; 216/79; 156/345.29; 156/345.33

(57) ABSTRACT

Provided herein is an apparatus and a method useful for manufacturing MEMS devices. An aspect of the disclosed apparatus provides a substrate comprising an etchable material exposed to a solid-state etchant, wherein the substrate and the solid-state etchant are disposed in an etching chamber. In some embodiments, the solid state etchant is moved into close proximity to the substrate. In other embodiments, a configurable partition is between the substrate and the solid-state etchant is opened. The solid-state etchant forms a gas-phase etchant suitable for etching the etchable material. In some preferred embodiments, the solid-state etchant is solid xenon difluoride. The apparatus and method are advantageously used in performing a release etch in the fabrication of optical modulators.

### CROSS-REFERENCE TO RELATED APPLICATION

This application claims the benefit of priority under 35 U.S.C. § 119(e) to U.S. Patent Application No. 60/613,423, filed on Sep. 27, 2004, the disclosure of which is incorporated by reference in its entirety.

### BACKGROUND OF THE INVENTION

1. Field of the Invention

The present disclosure relates generally to fabricating electronic devices. More particularly, the disclosure relates to an apparatus and method useful for fabricating a microelectromechanical systems device.

2. Description of the Related Art

Microelectromechanical systems (MEMS) include micromechanical elements, actuators, and electronics. Micromechanical elements may be created using deposition, etching, and/or other micromachining processes that etch away parts of substrates and/or deposited material layers or that add layers to form electrical and electromechanical devices. Some of these processes are similar to those originally developed for use in semiconductor manufacturing.

A spatial light modulator is an example of a MEMS. A variety of different types of spatial light modulators can be used for imaging applications. One type of a spatial light modulator is an interferometric modulator. An interferometric modulator may comprise a pair of conductive plates, one or both of which may be partially transparent and capable of relative motion upon application of an appropriate electrical signal. One plate may comprise a stationary layer deposited on a substrate, the other plate may comprise a metallic membrane suspended over the stationary layer. Such devices have a wide range of applications, and it would be beneficial in the art to utilize and/or modify the characteristics of these types of devices so that their features can be exploited in improving existing products and creating new products that have not yet been developed.

### SUMMARY OF CERTAIN EMBODIMENTS

The system, method, and devices of the invention each have several aspects, no single one of which is solely responsible for its desirable attributes. Without limiting the scope of this invention, its more prominent features will now be discussed briefly. After considering this discussion, and particularly after reading the section entitled “Detailed Description of Certain Embodiments” one will understand how the features of this invention provide advantages that include, for example, improved throughput, control, and process flexibility.

Provided herein is an apparatus and a method useful for manufacturing MEMS devices. An aspect of the disclosed apparatus provides a substrate comprising an etchable material exposed to a solid-state etchant, wherein the substrate and the solid-state etchant are disposed in an etching chamber. In some embodiments, the solid state etchant is moved into close proximity to the substrate. In other embodiments, a configurable partition is between the substrate and the solid-state etchant is opened. The solid-state etchant forms a gas-phase etchant suitable for etching the etchable material. In some preferred embodiments, the solid-state etchant is solid xenon difluoride. The apparatus and method are advantageously used in performing a release etch in the fabrication of optical modulators.

Some embodiments provide an apparatus for etching comprising a chamber, a support for a substrate on which a microelectromechanical systems device is formed, and solid xenon difluoride, wherein the support and the solid xenon difluoride are disposed within the chamber.

Other embodiments disclosed herein provide an apparatus for etching comprising an etchant module and an etching chamber, wherein the etching chamber comprises an interior, an exterior, and a support for a substrate therein, wherein the apparatus has a first configuration, in which the etchant module is disposed in the interior of the etching chamber and is in fluid communication with a substrate disposed on the support, and a second configuration, in which the etchant module is not in fluid communication with the substrate disposed on the support. In some embodiments, the etchant module is movable between a retracted position and an extended position; in the retracted position, the etchant module is substantially outside the etching chamber; and in the extended position the etchant module is substantially within the etching chamber.

Other embodiments provide an apparatus for etching comprising: an etching chamber; a support for a substrate on which microelectromechanical device is formed; an etchant module; and a means for exposing a substrate on the support to the etchant module within the etching chamber.

Other embodiments provide an apparatus for etching comprising a support for a substrate on which a microelectromechanical systems device is formed and solid xenon difluoride, wherein the support and the solid xenon difluoride are proximate for a vapor formed from the solid xenon difluoride to etch a substrate comprising an etchable material. In some embodiments, the support and solid xenon difluoride are less than about 10 cm apart.

Other embodiments disclosed herein provide a method for fabricating a microelectromechanical systems device and a microelectromechanical systems device fabricated according to the method, wherein the method comprises: supporting a substrate in an etching chamber comprising an interior, an exterior, and a support for a substrate; and disposing an etchant module in the interior of the etchant chamber and in fluid communication with the substrate, wherein a solid-state etchant is supported in the etchant module. In some embodiments, the microelectromechanical systems device is an interferometric modulator.

Other embodiments provide a method for fabricating a microelectromechanical systems device and a microelectromechanical systems device fabricated according to the method, wherein the method comprises: disposing within an etching chamber a substrate comprising an etchable material, and disposing within the etching chamber a solid etchant, wherein the solid etchant forms a gas-phase etchant capable of etching the etchable material.

Other embodiments provide a method for fabricating a microelectromechanical systems device and a microelectromechanical systems device fabricated according to the method, wherein the method comprises: disposing a substrate within an etching chamber; extending an etchant module into the etching chamber; and allowing the gas-phase etchant to etch the material. A solid etchant is supported on the etchant module, and the solid etchant forms a gas-phase etchant capable of etching a material on the substrate.

Other embodiments provide a method for fabricating a microelectromechanical systems device and a microelectromechanical systems device fabricated according to the method, wherein the method comprises: providing solid xenon difluoride within an etch chamber; supporting a substrate comprising an etchable material within the etch chamber; and etching the etchable material from the substrate with a vapor generated by the solid xenon difluoride.

Other embodiments provide a method for fabricating a microelectromechanical systems device and a microelectromechanical systems device fabricated according to the method, wherein the method comprises: supporting a substrate comprising an etchable material within the etch chamber; and positioning solid xenon difluoride sufficiently proximate to the substrate such that a vapor formed by the solid xenon difluoride etches the etchable material. In some embodiments, the support and solid xenon difluoride are less than about 10 cm apart.

### BRIEF DESCRIPTION OF THE DRAWINGS

These and other aspects of the invention will be readily apparent from the following description and from the appended drawings (not to scale), which are meant to illustrate and not to limit the invention.

FIG. 1 is an isometric view depicting a portion of one embodiment of an interferometric modulator display in which a movable mirror of a first interferometric modulator is in a reflective, or “on,” position at a predetermined distance from a fixed mirror and the movable mirror of a second interferometric modulator is in a non-reflective, or “off” position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of sets of row and column voltages that may be used to drive an interferometric modulator display.

FIG. 5A and FIG. 5B illustrate one exemplary timing diagram for row and column signals that may be used to write a frame of display data to the 3×3 interferometric modulator display of FIG. 3.

FIG. 6A is a cross section of the device of FIG. 1. FIG. 6B is a cross section of an alternative embodiment of an interferometric modulator. FIG. 6C is a cross section of an alternative embodiment of an interferometric modulator

FIG. 7A-FIG. 7E illustrate in cross section certain intermediate structures in the fabrication of an embodiment of an interferometric modulator.

FIG. 8 illustrates an embodiment of an apparatus useful for performing a release etch in the fabrication of a MEMS device.

FIG. 9 is a flowchart illustrating an embodiment of a method for performing a release etch using the apparatus of FIG. 8.

FIG. 10A is a perspective view of an embodiment of an apparatus suitable for performing a release etch in the fabrication of a MEMS device. FIG. 10B and FIG. 10C are detail views of a module for the apparatus illustrated in FIG. 10A. FIG. 10D and FIG. 10E are top views and cross sections, respectively, of another embodiment of an etching chamber.

FIG. 11A-FIG. 11D illustrate alternative embodiments for an etchant module.

FIG. 12A and FIG. 12B illustrate alternative embodiments for etching chambers.

FIG. 13 is a flowchart illustrating an embodiment of a method for performing a release etch using the apparatus illustrated in FIG. 10A or FIG. 12A.

### DETAILED DESCRIPTION OF CERTAIN EMBODIMENTS

As described in more detail below, preferred embodiments disclosed herein provide an etching chamber comprising a support for a MEMS substrate and a solid etchant disposed within the etching chamber. In some embodiments, the solid etchant is supported in a module that is movable between a position distal of the support for the MEMS substrate and a position proximal of the support. In other embodiments, a configurable partition between the MEMS substrate and the solid etchant is opened. In some preferred embodiments, the solid etchant is xenon difluoride. Also described herein are embodiments of methods of using the apparatus in the fabrication of a MEMS device, and in particular, an interferometric modulator. These and other embodiments are described in greater detail below.

The following detailed description is directed to certain specific embodiments of the invention. However, the invention can be embodied in a multitude of different ways. In this description, reference is made to the drawings wherein like parts are designated with like numerals throughout. As will be apparent from the following description, the invention may be implemented in any device that is configured to display an image, whether in motion (e.g., video) or stationary (e.g., still image), and whether textual or pictorial. More particularly, it is contemplated that the invention may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures (e.g., tile layouts), packaging, and aesthetic structures (e.g., display of images on a piece of jewelry). More generally, the invention may be implemented in electronic switching devices.

Spatial light modulators used for imaging applications come in many different forms. Transmissive liquid crystal display (LCD) modulators modulate light by controlling the twist and/or alignment of crystalline materials to block or pass light. Reflective spatial light modulators exploit various physical effects to control the amount of light reflected to the imaging surface. Examples of such reflective modulators include reflective LCDs, and digital micromirror devices.

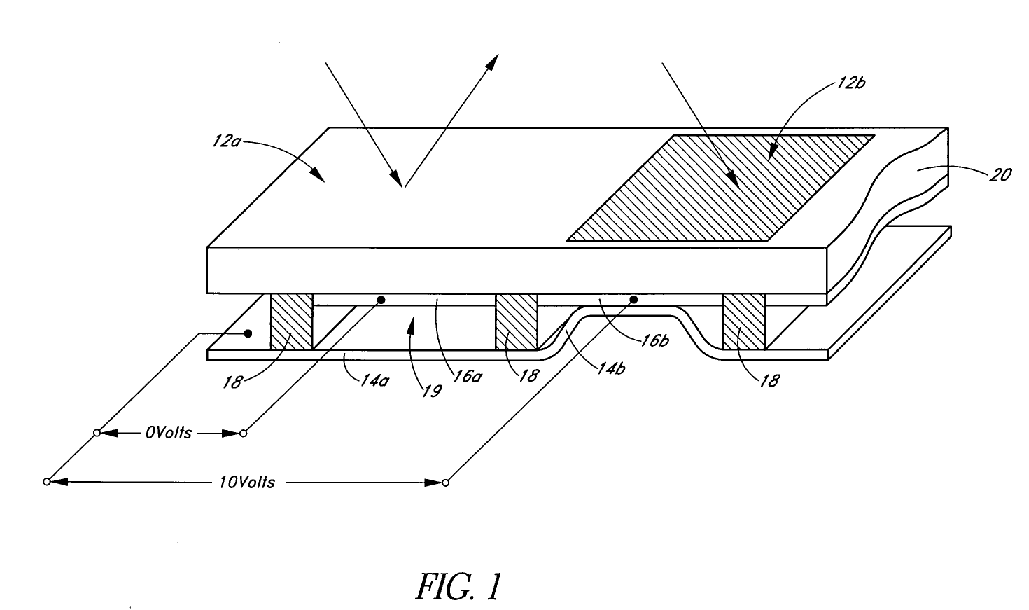

Another example of a spatial light modulator is an interferometric modulator that modulates light by interference. One interferometric modulator display embodiment comprising a reflective MEMS display element is illustrated in FIG. 1. In these devices, the pixels are in either a bright or dark state. In the bright (“on” or “open”) state, a bi-stable display element reflects incident light to a user. When in the dark (“off” or “closed”) state, a bi-stable display element and reflects little visible light to the user. Depending on the embodiment, the display 110 may be configured to reflect more visible light in the “off” state than in the “on” state, i.e., the light reflectance properties of the “on” and “off” states are reversed. MEMS pixels can also be configured to reflect only selected colors, producing a color display rather than black and white.

FIG. 1 is an isometric perspective view depicting two adjacent pixels in a row of one embodiment of a visual display, comprising a MEMS interferometric modulator. An interferometric modulator display comprises a row/column array of these interferometric modulators. Each interferometric modulator includes a pair of mirrors positioned at a distance from each other to form a resonant optical cavity. In one embodiment, at least one of the mirrors in partially transmissive. In one embodiment, one of the mirrors may be moved between at least two positions. In the first position, the movable mirror is positioned at a first distance from the other mirror so that the interferometric modulator is predominantly reflective. In the second position, the movable mirror is positioned at a different distance, e.g., adjacent to the fixed mirror, such that the interferometric modulator is predominantly absorbing.

The depicted portion of the pixel array includes two adjacent interferometric modulators 12a and 12b in a row. In the depicted embodiment of the interferometric modulator, a movable mirror 14a is illustrated in the reflective (“relaxed”, “on”, or “open”) position at a predetermined distance from a fixed, partial mirror 16a, 16b. The movable mirror 14b of the interferometric modulator 12b is illustrated in the non-reflective (“actuated”, “off”, or “closed”) position adjacent to the partial mirror 16b.

The fixed mirrors 16a, 16b are electrically conductive, and may be fabricated, for example, by depositing layers of chromium and indium-tin-oxide onto a transparent substrate 18 that are patterned into parallel strips, and may form row electrodes. The movable mirrors 14a, 14b along the row may be formed as a series of parallel strips of a deposited metal layer or layers (orthogonal to the row electrodes 16a, 16b) on the substrate 18, with aluminum being one suitable material, and may form column electrodes.

With no applied voltage, a cavity 19 exists between the two layers 14, 16. However, when a potential difference is applied to a selected row and column, the capacitor formed at the intersection of the row and column electrodes at the corresponding pixel charges, and electrostatic forces pull the electrodes together. If the voltage is high enough, the movable electrode is forced against the stationary electrode (a dielectric material may be deposited on the stationary electrode to prevent shorting and control the separation distance) as illustrated by the pixel on the right in FIG. 1. The behavior is the same regardless of the polarity of the applied potential difference. In this way, row/column actuation can control the reflective vs. non-reflective state of each pixel.

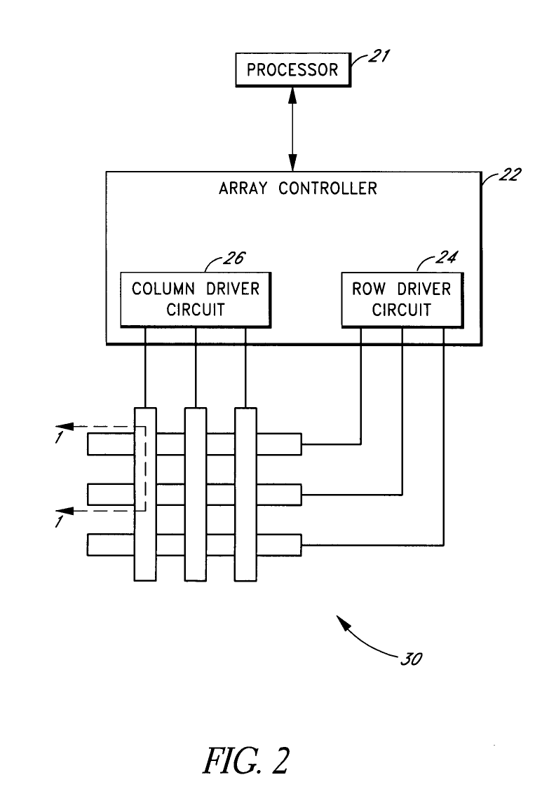

FIG. 2 through FIG. 5 illustrate one exemplary process and system for using an array of interferometric modulators in a display application. FIG. 2 is a system block diagram illustrating one embodiment of an electronic device that may incorporate aspects of the invention. In the exemplary embodiment, the electronic device includes a processor 20 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 20 may be configured to execute one or more software modules. In addition to executing an operating system, the processor may be configured to execute one or more software applications, including a web browser, a telephone application, an email program, or any other software application.

In one embodiment, the processor 20 is also configured to communicate with an array controller 22. In one embodiment, the array controller 22 includes a row driver circuit 24 and a column driver circuit 26 that provide signals to the array 30. The cross section of the array illustrated in FIG. 1 is shown by the lines 1-1 in FIG. 2. Portions of the array controller 22 as well as additional circuitry and functionality may be provided by a graphics controller which is typically connected between the actual display drivers and a general purpose microprocessor. Exemplary embodiments of the graphics controller include 69030 or 69455 controllers from Chips and Technology, Inc., the S1D1300 series from Seiko Epson, and the Solomon Systech 1906.

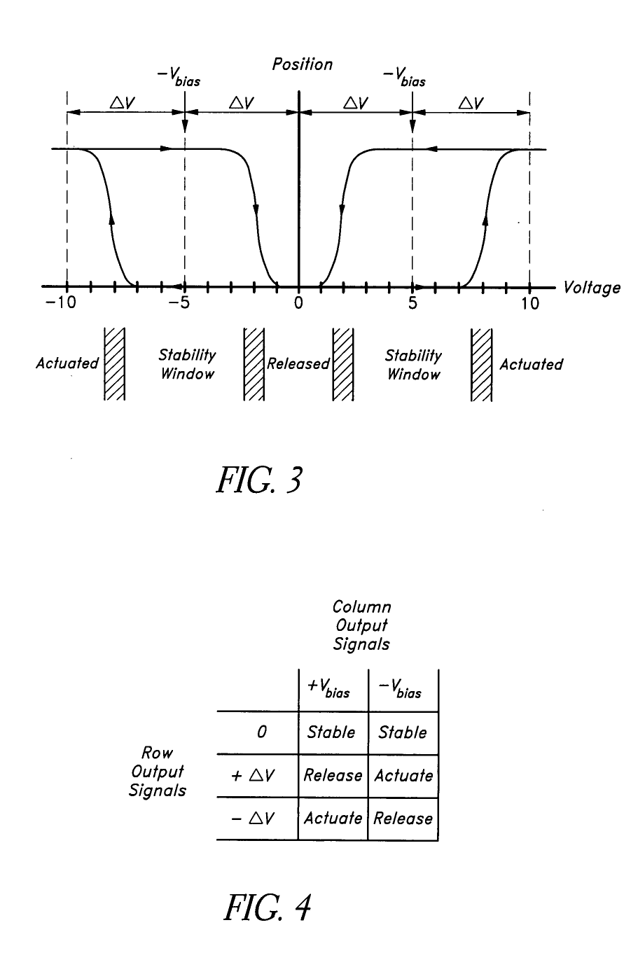

For MEMS interferometric modulators, the row/column actuation protocol may take advantage of a hysteresis property of these devices illustrated in FIG. 3. It may require, for example, a 10 volt potential difference to cause a pixel to deform from the relaxed state to the actuated state. However, when the voltage is reduced from that value, the pixel may not relax until the voltage drops below 2 volts. There is thus a range of voltage, about 3 V to about 7 V in the example illustrated in FIG. 3, where there exists a stability window within which the device will remain in whatever state it started in. The row/column actuation protocol is therefore designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving mirrors, this stable state can be held at a voltage within the hysteresis window with almost no power dissipation. Essentially no current flows into the pixel if the mirror is not moving and the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, asserting the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of other protocols for driving row and column electrodes of pixel arrays to produce display frames are also well known and may be used in conjunction with the present invention.

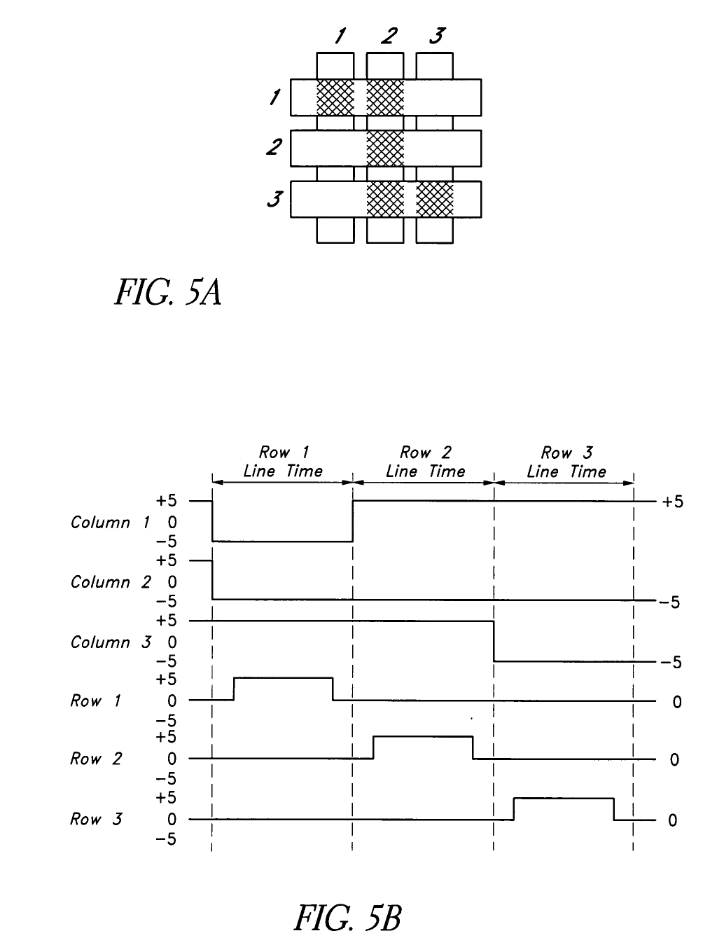

FIG. 4 and FIG. 5 illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV. Relaxing the pixel is accomplished by setting the appropriate column to +V_{bias}, and the appropriate row to the same +ΔV. In those rows where the row voltage is held at zero volts, the pixels are stable in whatever state they were originally in, regardless of whether the column is at +V_{bias}, or −V_{bias}.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. In this state, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the present invention.

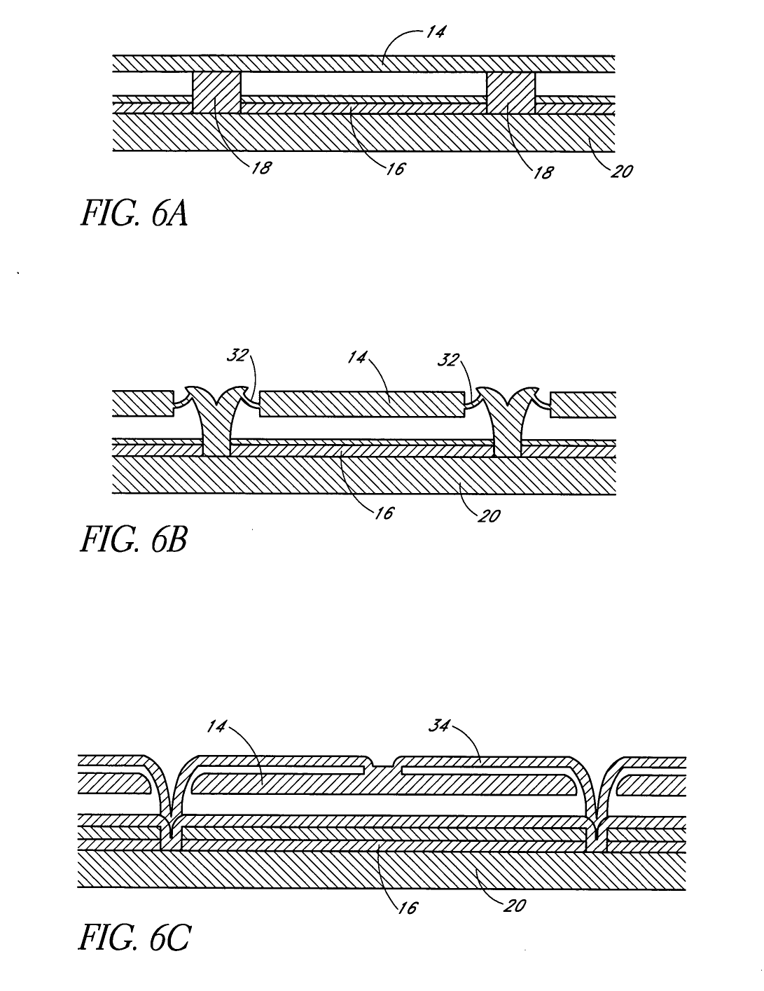

The details of the structure of interferometric modulators that operate in accordance with the principles set forth above may vary widely. For example, FIG. 6A-FIG. 6C illustrate three different embodiments of the moving mirror structure. FIG. 6A is a cross section of the embodiment of FIG. 1, where a strip of metal material 14 is deposited on orthogonally extending supports 18. In FIG. 6B, the moveable mirror is attached to the supports at the corners only, on tethers 32. In FIG. 6C, the mirror 14 is suspended from a deformable film 34. This embodiment has benefits because the structural design and materials used for the mirror 14 can be optimized with respect to the optical properties, and the structural design and materials used for the deformable layer 34 can be optimized with respect to desired mechanical properties. The production of various types of interferometric devices is described in a variety of published documents, including, for example, U.S. Published Application 2004/0051929. A wide variety of well known techniques may be used to produce the above described structures involving a series of material deposition, patterning, and etching steps.

Interferometric modulators of the general designs described above and disclosed in U.S. Pat. No. 5,835,255 and in U.S. Patent Publication No. ##, the disclosures of which are incorporated by reference, and those illustrated in FIG. 6A-FIG. 6C include a cavity 19 between the mirrors 14 and 16 through which the mirror 14 moves with respect to the mirror 16. In some embodiments, the cavity 19 is created by forming a sacrificial layer that is removed in a latter stage in the processing, as described in greater detail below.

U.S. Provisional App. No. 60/613,466 entitled “Device and Method for Interferometric Modulation Having Oxide-Stops” filed on Sep. 27, 2004, the disclosure of which is incorporated by reference, also discloses manufacturing techniques for the fabrication of an interferometric modulator. A sacrificial layer is formed and etched away to release the secondary mirror/conductor from the primary mirror/conductor, thereby forming a cavity and permitting movement therebetween. This etch is also referred to herein as a “release etch,” because the flexible membrane is released by the etch thereby permitting flexure of this membrane.

As discussed more fully below, in some preferred embodiments, solid XeF₂ is a source of a gas-phase etchant used in the release etch. As such, the following description refers to solid XeF₂ as the source of the gas-phase etchant, although those skilled in the art will understand that the disclosure is not so limited. Methods and apparatus for enhancing the efficiency of the XeF₂ release etch are also described more fully below. As discussed in greater detail below, materials etchable by XeF₂ include materials comprising silicon, titanium, zirconium, hafnium, vanadium, tantalum, niobium, molybdenum, and tungsten.

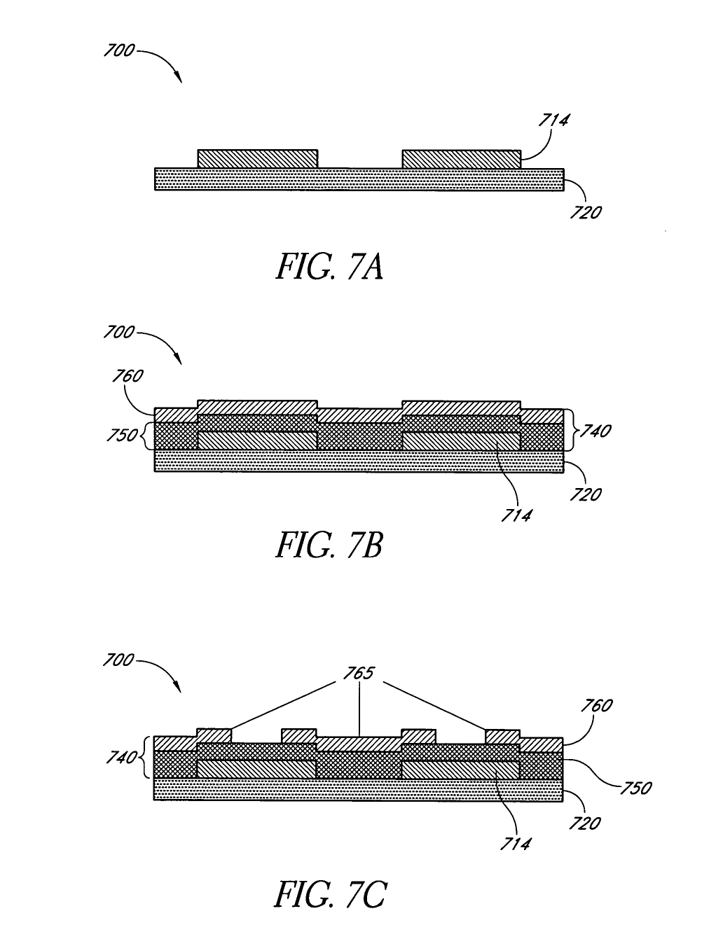

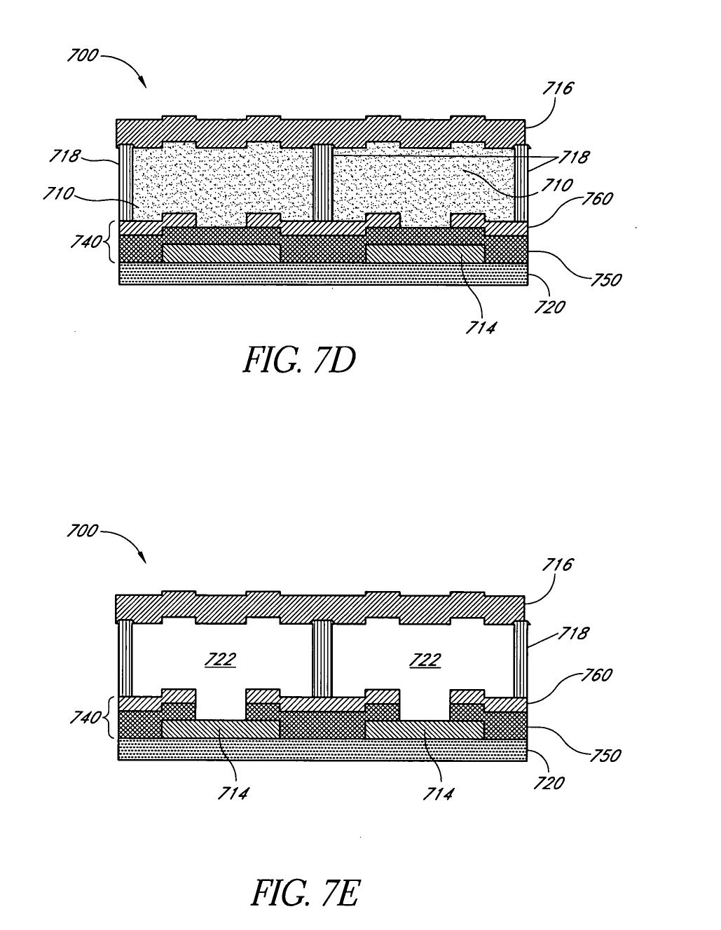

A brief description of certain steps in the fabrication of an embodiment of an interferometric modulator follows, and is illustrated schematically in cross section in FIG. 7A-FIG. 7E. Some embodiments of the illustrated process use semiconductor manufacturing techniques known in the art, for example photolithography, deposition, masking, etching, and the like. Deposition steps include “dry” methods, for example, chemical vapor deposition (CVD), and “wet” methods, for example, spin coating. Etching steps include “dry” methods, for example, plasma etch, and “wet” methods. Those skilled in the art will understand that a range of methods are useful in the fabrication of the optical modulator, and that the process described below is only exemplary.

FIG. 7A illustrates a stage in the fabrication of a interferometric modulator 700 in which an optical stack is formed on a substrate 720. The optical stack comprises the fixed or primary mirror 714 discussed above. In some embodiments, the optical stack further comprises a transparent conductor, for example, an indium tin oxide layer, and/or a supporting layer, for example, a silicon oxide layer. Some embodiments comprise a metallic mirror, for example, chromium, aluminum, titanium, and/or silver. Other embodiments comprise a dielectric mirror. The optical stack is formed by methods known in the art, for example, deposition, patterning, and etching.

In FIG. 7B, a supporting layer 740 has been formed over the optical stack and substrate 720. In the illustrated embodiment, the supporting layer 740 comprises a lower or “bulk” portion 750 and an upper layer or “stop” portion 760. The lower portion 750 comprises a material that is removable in a later etching step, for example, molybdenum, silicon, a silicon-containing material (e.g., silicon nitride, silicon oxide, etc.), tungsten, and/or titanium. The upper portion 760 comprises a material that resists the etchant used to etch the lower portion 750, for example, a metal such as aluminum, silver, chromium, and/or titanium. In some embodiments, the upper portion 760 comprises a dielectric material, for example, a metal oxide and/or aluminum oxide. In some embodiments, the lower portion 750 and upper portion 760 is graded. Some embodiments do not comprise a supporting layer.

FIG. 7C illustrates a stage in the fabrication of the device 700 in which the upper portion 760 of the supporting layer has been patterned and etched to form a variable thickness supporting layer 765, as well as to expose sections of the lower portion 750 of the supporting layer. The patterning is performed using any method known in the art, for example, using a photoresist. In the illustrated embodiment, unmasked regions of the upper portion 760 of the supporting layer were etched, while substantial portions of the lower portion 750 were not.

FIG. 7D illustrates a stage in which a sacrificial layer 710 has been deposited on the supporting layer 740. The sacrificial layer was patterned, etched, and planarized, and support posts 718 formed therein. A second mirror/upper electrode assembly 716 was formed over the sacrificial layer 710 and posts 718 by deposition, patterning, and etching. The sacrificial layer 710 comprises a material that is selectively etchable relative to the other materials exposed to a selected etchant. Suitable materials and etchants are discussed in greater detail below. In some preferred embodiments, the sacrificial layer 710 comprises molybdenum and/or silicon.

FIG. 7E illustrates the device 700 after etching the sacrificial layer 710. This etch step is referred to herein as a “sacrificial etch” and/or a “release etch.” Methods and procedures for performing a release etch are discussed in greater detail below. In the illustrated embodiment, parts of the lower portion 750 of the supporting layer were also etched. In some embodiments, the lower portion 750 is partially etched or not etched at all. In other embodiments, the supporting layer 740 does not comprise a lower portion 750. In the illustrated embodiment, removal of the sacrificial layer 710 and portions of the lower portion 750 of the supporting layer forms a cavity 722. Suitable etchants are discussed in greater detail below. In some preferred embodiments, the etchant used in the sacrificial and/or release etch comprises xenon difluoride. Without being bound by any theory, XeF₂ is believed to be a source of F₂ gas, which is the active etching species.

At ordinary temperatures and pressures, XeF₂ is a crystalline solid that sublimes with a vapor pressure of about 3.8 Torr at room temperature (0.5 kPa at 25° C.). XeF₂ vapor etches certain materials without the need to generate a plasma. Materials etchable using XeF₂ vapor include silicon, molybdenum, and titanium, which are selectively etched over other materials including silicon dioxide (SiO₂), aluminum oxide (Al₂O₃), aluminum, and chromium. At ambient temperature, XeF₂ has a vertical etch rate of about 50 Å/s for molybdenum and about 350 Å/s for silicon. In comparison, SiO₂, Al, and Al₂O₃ are substantially not etched by XeF₂. Etch rates are known in the art, as disclosed, for example, in IEEE J. Microelectromech. Syst., 1996, 5(4), 262; IEEE J. Microelectromech. Syst., 1996, 12(6), 761. In some embodiments, the partial pressure of the XeF₂ is from about 0.1 torr (13 Pa) to about 10 torr (1.3 kPa). Process temperatures range from ambient temperature to about 100° C.

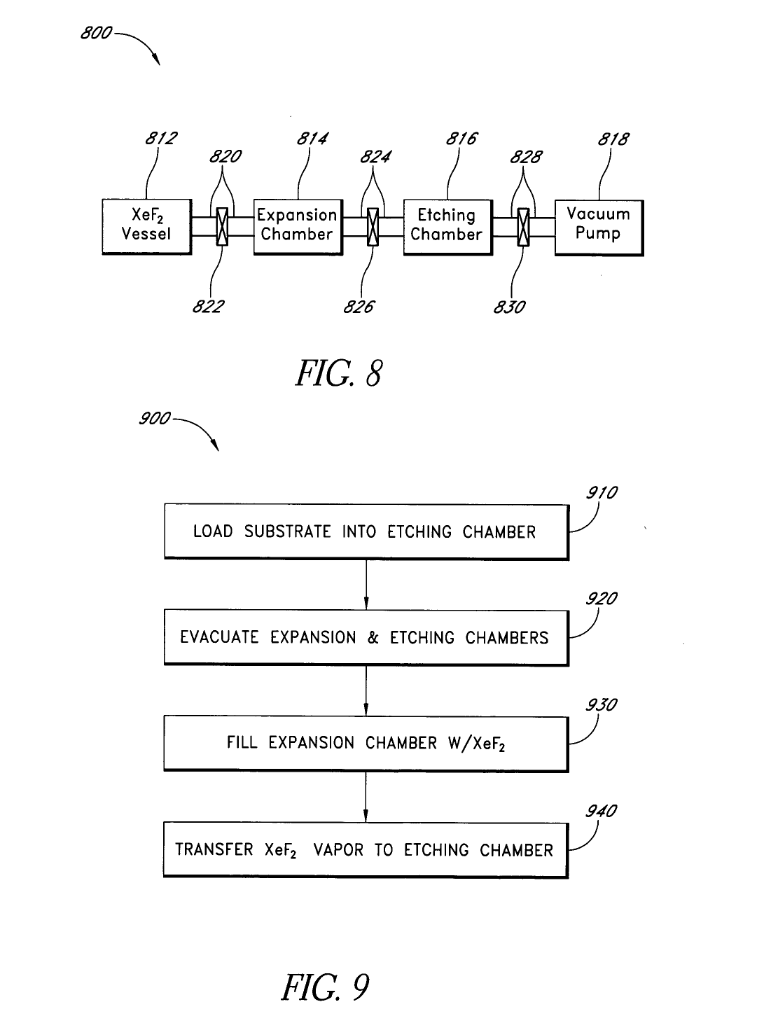

FIG. 8 illustrates an apparatus 800 useful for implementing a XeF₂ etching step. The apparatus 800 comprises a XeF₂ vessel 812 in which XeF₂ crystals are housed, an expansion chamber 814, an etching chamber 816, and a vacuum source 818. The XeF₂ vessel 812 is fluidly connected to the expansion chamber 814 through a first conduit 820 and a first valve 822. The expansion chamber 814 is in turn fluidly connected to the etching chamber 816 through a second conduit 824 and a second valve 826. The etching chamber 816 is fluidly connected to the vacuum source 818 through a third conduit 828 and a third valve 830.

FIG. 9 illustrates a method 900 for etching a substrate using XeF₂ with reference to the apparatus illustrated in FIG. 8. In step 910, a substrate or batch of substrates to be etched (not illustrated), is loaded into the etching chamber 816.

In step 920, the second and third valves 826 and 830 are opened, fluidly connecting the expansion chamber 814 and etching chamber 816 to the vacuum source 818, thereby evacuating the expansion chamber 814 and etching chamber 816. In step 920, the first valve 822 between the XeF₂ vessel 812 and the expansion chamber 814 remains closed.

In step 930, the second valve 826 is closed, and the first valve 822 is opened. Opening the first valve 822 permits XeF₂ vapor to fill the expansion chamber 814 from the XeF₂ vessel 812.

In step 940, the second valve 826 between the expansion chamber 814 and the etching chamber 816 is opened, and the first and third valves 822 and 830 are closed. Opening the second valve 826 permits transfers XeF₂ from the expansion chamber 814 to the etching chamber 816, which etches the substrate(s) therein.

Steps 910-930, in which no etching occurs, take time, thereby reducing the throughput of the apparatus 800. In some embodiments, the conduits (820, 824, and 828) and valves (822, 826, and 828) fluidly connecting the XeF₂ vessel 812, expansion chamber 814, etching chamber 816, and vacuum source 818 also reduce one or more mass and/or fluid transport characteristics of the apparatus 800.

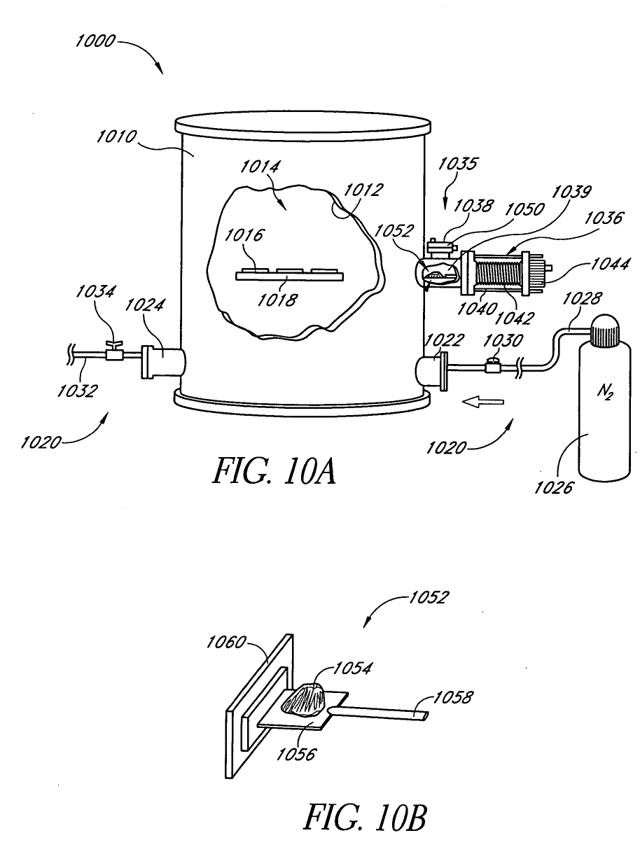

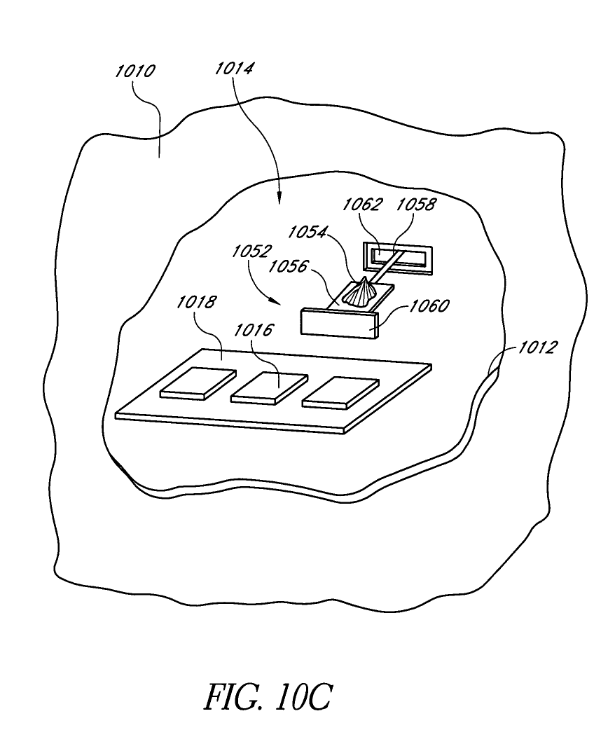

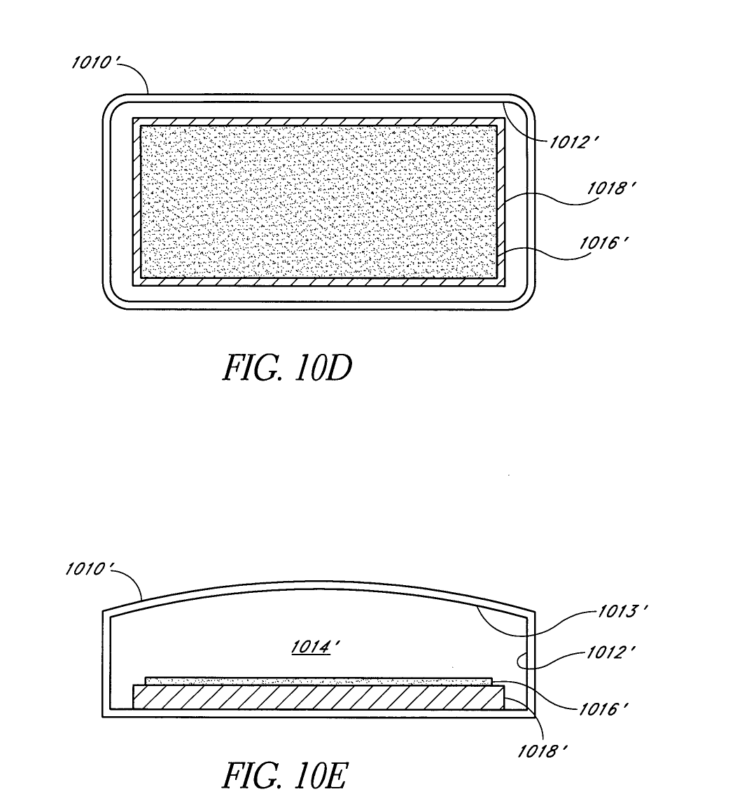

An embodiment of an apparatus 1000 illustrated in FIG. 10A-FIG. 10C permits solid XeF₂ and the substrate-to-be-etched to reside in close proximity within the same chamber during the etching step. FIG. 10A illustrates an etching chamber 1010 comprising inner sidewalls 1012 defining a central or main cavity 1014 therein. FIG. 10A includes a cut-away view of the chamber 1010 showing a plurality of substrates-to-be-etched 1016 disposed on a substrate support 1018, within the central cavity 1014. In the illustrated embodiment, the etching chamber 1010 is substantially cylindrical; however, those skilled in the art will understand that the etching chamber 1010 can have any suitable shape.

FIG. 10D illustrates a top view of an embodiment of an etching chamber 1010′ in which the inner sidewalls 1012′ of the etching chamber substantially match the size and shape of the substrate support 1018′, which is in turn, substantially similar to the size and shape of the substrate 1016′. In the illustrated embodiment, the substrate is substantially rectangular. Those skilled in the art will understand that other configurations are possible. FIG. 10E is a cross section view of the etching chamber 1010′. In the illustrated embodiment, the top of the etching chamber 1013′ along with the sidewalls 1012′ defines the central cavity 1014′. In some embodiments, the geometry of the central cavity 1014′ is configured to improve the efficiency of the etching step performed therein. For example, in the illustrated embodiment, if the distance between the top of the etching chamber 1013′ and the substrate 1016′ is relatively small, the volume of the etching chamber 1014′ is insufficient to hold a sufficient amount of etchant, for example, XeF₂ vapor, to efficiently etch the substrate 1016′. On the other hand, if the distance between the top of the etching chamber 1013′ and the substrate 1016′ is relatively large, XeF₂ vapor from near the top 1013′ will take a significant time to diffuse to the substrate 1016′. The etching chamber 1010′ illustrated in FIG. 10D and FIG. 10E is configured for etching a single substrate at a time. In other embodiments, the etching chamber is configured for processing a plurality of substrates simultaneously. Those skilled in the art will understand that the dimensions of the etching chamber will depend on factors including the sizes of the substrate or substrates, the amount of material to be etched, the nature of other processes that are performed in the etching chamber. In some embodiments, the lateral dimensions, e.g., the length and width, of the etching chamber are up to about 20% larger than the size of the substrate. For example, some embodiments provide an etching chamber 1010′ with a length and/or width of from greater than about 100 mm to about 120 mm for a 100-mm diameter substrate. Other embodiments provide for a 370-mm×470-mm substrate, an etching chamber 1010′ with dimensions of from greater than about 370 mm to about 450 mm, by from greater than about 470 mm to about 570 mm. In some embodiments, the lateral dimensions, e.g., the length and width, of the etching chamber are up to about 10% larger than the size of the substrate.

Referring back to FIG. 10A-FIG. 10C, the etching chamber 1010 optionally includes one or more other components useful for performing other processing tasks, for example, deposition, patterning, etching, testing, packaging, and the like (not illustrated). In some embodiments, the substrate holder 1018 includes optional features, including, for example, a heater, one or more translation stages, and/or other features known in the art useful in processing the substrate(s) 1016.

In some embodiments, the inner sidewalls 1012 of the etching chamber 1010 and/or the components enclosed therein comprise one or more materials that are not etched or are minimally etched by XeF₂. Such materials include without limitation, stainless steel, aluminum, nickel, nickel alloys, monel, hastelloy, glass, fused silica, alumina, sapphire, polymer resins, acrylic, polycarbonate, polytetrafluoroethylene (Teflon®), polychlorotrifluoroethylene (Kel-F®, Tefzel®), perfluoroelastomers (e.g., Kalrez®), and alloys, blends, copolymers, and composites thereof. Components include windows, the substrate stage 1018, and other components that are described below. In some embodiments, other materials are used. For example, in some embodiments, one or more of the components is affected by XeF₂ and is disposable and/or replaceable.

Returning to FIG. 10A, the illustrated apparatus 1000 also comprises a purge system 1020 fluidly connected to the etching chamber 1010 through a purge inlet 1022 and a purge outlet 1024. A source of purge gas 1026 is fluidly connected to the purge inlet 1022 through line 1028 and an inlet valve 1030. The purge gas is any suitable purge gas known in the art, for example, nitrogen, helium, argon, neon, and combinations thereof. The source of purge gas is any source known in the art, for example, a compressed gas cylinder, a gas generator, a liquefied gas, and the like. In some embodiments, the purge gas comprises another gas. The purge outlet 1024 is fluidly connected to a vacuum source (not illustrated) through outlet valve 1034 and line 1032. In some embodiments, the purge system does not comprise a purge outlet. For example, in some of these embodiments, the inlet valve 1030 and the outlet valve 1034 are fluidly connected to a manifold (not illustrated), and the manifold is fluidly connected to the purge inlet 1022.

The apparatus 1000 is also equipped with a opening (not illustrated) through which the substrates 1016 are loaded and unloaded from the apparatus 1000. The opening is of any type known in the art, for example, a gate valve between the etching chamber 1010 and a handling chamber (not illustrated).

In the illustrated embodiment, a solid etchant, for example, solid XeF₂, is held in an etchant holding unit 1035 mounted to the etching chamber 1010. The illustrated apparatus 1000 comprises one etchant holding unit 1035. Other embodiments comprise a plurality of etchant holding units. In the illustrated embodiment, etchant unit 1035 is equipped with a translation device 1036 that comprises rails 1040, bellows 1042, and a threaded shaft (not illustrated) engaging a threaded coupler (not illustrated) and a rotatable control 1044. The illustrated translation device 1036 further comprises an arm (not illustrated) disposed within the bellows 1042. Rotating the rotatable control 1044 rotates the threaded shaft in the threaded coupler, thereby translating (extending or retracting) the arm. In the illustrated embodiment, the bellows 1042 is compressed or expanded to accommodate the translation. Those skilled in the art will understand that other mechanisms are useful for the translation device 1036, for example, a pantograph, a rack and pinion, a piston and cylinder, a rail, and the like. Other mechanisms include motors, stepper motors, solenoids, pneumatics, and/or hydraulic devices. In other embodiments, the motion is rotational, as described in greater detail below, or has another type of motion known in the art. In some embodiments, the translation device 1036 is automated, for example, controlled using a computer and/or microprocessor (not illustrated). In some embodiment, the computer and/or microprocessor controls also other functions of the apparatus, for example, the purge system, substrate loading, substrate unloading, and/or loading solid XeF₂.

The etchant holding unit 1035 comprises an access port 1038. The access port 1038 comprises a passageway therethrough that opens into an open inner region 1039 therein. In the illustrated embodiment, the access port 1038 also includes a door 1050 that provides access to the inner region 1039 of the access port. In some embodiments, the door 1050 is automated, thereby permitting automated loading of XeF₂. In the illustrated embodiment, solid XeF₂ is loaded into the XeF₂ unit 1035 through the door 1050. In some embodiments, the open inner region 1039 is fluidly connected to a purge system, for example, a source of purge gas and/or a vacuum source (not illustrated). The purge system is useful, for example, when solid XeF₂ is loaded into the XeF₂ unit 1035.

Also illustrated in FIG. 10A through a cutaway in the access port 1038 is a module 1052 for supporting solid XeF₂. An enlarged view of the module 1052 is provided in FIG. 10B. In the illustrated embodiment, the module 1052 includes a platform 1056 that supports a solid XeF₂ sample 1054. The platform 1056 is secured to a rod 1058, which is in turn secured to the arm of the translation device 1036. Accordingly, the translation device 1036 is capable of longitudinally positioning the module 1052 on which the solid XeF₂ 1054 is supported.

In FIG. 10A, the module 1052 is in a retracted position, within the inner region 1039 of the access port 1038. The module 1052 is not disposed in the central cavity 1014 of the chamber 1010. In the illustrated configuration, the access port 1038 is isolated from the central cavity 1014 of the chamber 1010 such that vapor from the solid XeF₂ 1054 is substantially contained within the access port 1038 and does not enter the central cavity 1014 of the chamber 1010. In the illustrated retracted position, solid XeF₂ 1054 is loaded on the module 1052 through the door 1050.

In an embodiment of the module 1052 illustrated in FIG. 10B, the solid XeF₂ 1054 is supported on the platform 1056. In the illustrated embodiment, a faceplate 1060 is secured to the platform 1056. The faceplate 1060 is sized and shaped to engage a matching opening (illustrated as part 1062 in FIG. 10C) in the sidewall 1012 of the chamber. In some embodiments, in the retracted position, the module 1052 is substantially sealed from the cavity 1014 of the chamber. For example, in some embodiments, the faceplate 1060 and/or the matching opening 1062 comprises a gasket and/or seal, which assists in substantially retaining XeF₂ and/or F₂ vapor from entering the chamber 1010 when the module 1052 is in the retracted position. In some embodiments, the module 1052 in the retracted position is not substantially sealed from the cavity 1014 of the chamber. In some embodiments, the module 1052 comprises a locking mechanism or mechanisms, useful for example, for maintaining the module in the retracted position and/or extended position. Suitable locking mechanisms are known in the art, for example, a latch between the faceplate 1060 and the sidewall 1012 of the chamber. In some embodiments, the locking mechanism is under automated control, for example, interlocked with the translation device 1036.

The faceplate 1060 physically separates the inner region 1039 of the access port from the central cavity 1014 when the module 1052 is in the retracted position. In the illustrated embodiment, the inner region 1039 of the access port has a relatively small volume, and consequently, relatively poor mass transport characteristics. Even if the faceplate 1060 were absent, when the module 1052 is in the retracted position, XeF₂ vapor diffuses slowly into the central cavity 1014. In the illustrated embodiment, the mass transport conditions translate into many minutes to hours for the partial pressure of XeF₂ to reach the equilibrium pressure of 3.8 Torr within the cavity 1014 with the module 1052 in the retracted position, even absent the faceplate 1060.

In the embodiment illustrated in FIG. 10B, the platform 1056 of the XeF₂ module 1052 does not include sidewalls or a backwall, thereby reducing the number of barriers between the solid XeF₂ 1054 and the substrate 1016. In other embodiments, the platform 1056 comprises one or more depressions and/or spoon-shaped areas in which the solid XeF₂ is placed. In some embodiments, the platform 1056 comprises one or more sidewalls and/or backwalls. In some embodiments, the platform 1056 comprises a grate and/or mesh, thereby providing improved mass transport through the platform 1056 by increasing the surface area of the solid etchant 1054 exposed the atmosphere. In some embodiments, the platform comprises a plurality of raised areas supporting the solid XeF₂ 1054, for example a surface with corrugations and/or a raised grid. In some embodiments, the platform 1056 comprises a heater. Those skilled in the art will understand that in other embodiments, the platform 1056 has different configurations.

FIG. 10C is a cutaway view through the sidewall 1012 of the chamber 1010, illustrating the XeF₂ module 1052 in an extended position. In the extended position, the XeF₂ module extends into the central cavity 1014 of the chamber. The translation stage 1036 is adjusted to extend the platform 1056 supporting the solid XeF₂ 1054 through an opening 1062 in the sidewall 1012 and into the central cavity 1014 of the chamber, thereby exposing the substrate 1016 to XeF₂ vapor.

In some embodiments, in the extended position, the module 1052 is proximate to the substrate 1016. In some embodiments, the distance between the module 1052 and the substrate 1016 is not more than from about 1 cm to about 10 cm. In other embodiments, the distance is not more than about 0.5 cm, 2 cm, 3 cm, 4 cm, 5 cm, 6 cm, 7 cm, 8 cm, or 9 cm. For example, in some embodiments in which the substrate-to-be-etched is not larger than about 300 mm (8″), the distance is not greater than about 2 cm. In some embodiments in which the substrate-to-be-etched is at least about 300 mm, the distance is greater than about 5 cm. In other embodiments, the distance between the module 1052 and the substrate 1016 has another value. In the illustrated embodiment, the faceplate 1060 is situated between the module 1052 and the substrate 1016. In other embodiments, the relative positions of the module 1052 and the substrate 1016 are different, for example with the module 1052 above or below the substrates, or to one side, such that the faceplate 1060 is not between the module 1052 and the substrate 1016.

The illustrated embodiment eliminates the conduits and/or pipes between the solid XeF₂ and the substrates-to-be-etched, thereby provided improved mass transport compared to the apparatus 800 illustrated in FIG. 8. Furthermore, the disposition of the solid XeF₂ within the cavity 1014 permits the vapor pressure of the XeF₂ in the cavity 1014 to equilibrate rapidly.

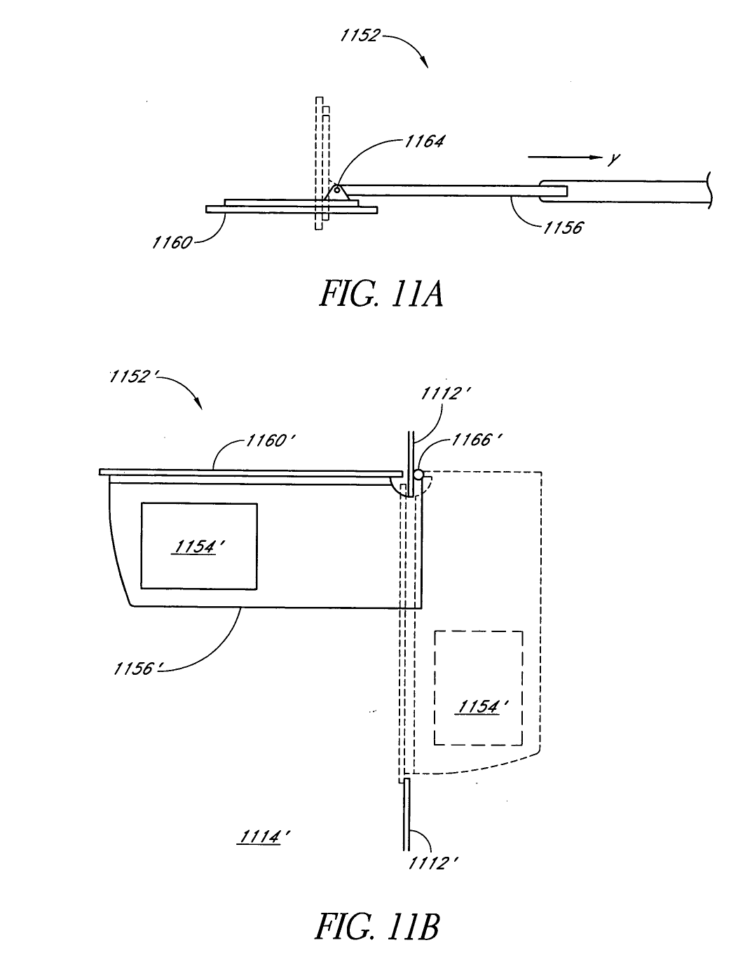

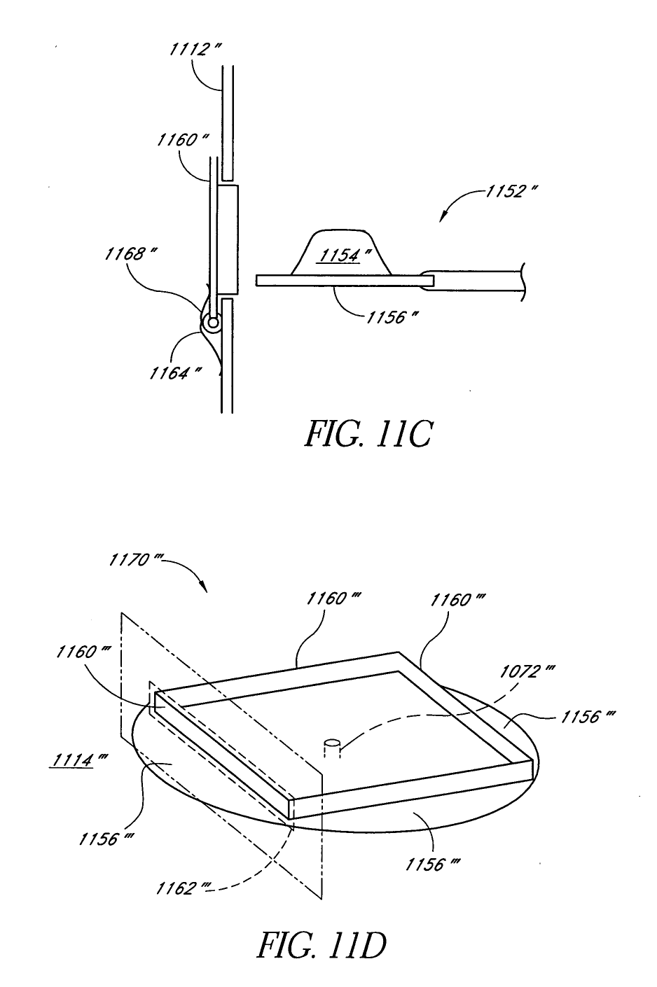

FIG. 11A illustrates a side view of an embodiment of a module 1152 in which the faceplate 1160 is pivotably attached to the platform 1156 using hinge 1164. When the module 1152 is in the extended position, the faceplate 1160 pivots downwards around the hinge 1164 as illustrated in solid lines in FIG. 11A. When the module 1152 is retracted in direction y, the faceplate 1160 engages the opening in the sidewall (not illustrated), thereby pivoting the faceplate 1160 into the position illustrated in phantom in FIG. 11A.

FIG. 11B illustrates a top view of an embodiment of a module 1152′ that pivotably moves from an extended position (solid lines) to a retracted position (phantom lines). In the illustrated embodiment, the module 1152′ comprises a platform 1156′ mounted to a pivot point 1166′. A faceplate 1160′ is mounted to an edge of the platform 1156′. Solid XeF₂ 1154′ is supported on the platform 1156′. In the extended position, the XeF₂ 1154′ is positioned within the cavity 1114′ of the etching chamber. When the module 1152′ is pivoted into the retracted position, the faceplate 1160′ seals against an inner sidewall 1112′ of the chamber, thereby isolating the XeF₂ 1154′ from the cavity 1114′.

FIG. 11C illustrates a side view of an embodiment of a faceplate 1160″ pivotably mounted to the inner sidewall 1112″ of the chamber using hinges 1164″. In the illustrated embodiment, the module 1152″ does not comprise a faceplate. A spring 1168″ maintains the faceplate 1160″ in a closed position when the module 1152″ is in the retracted position. As the module 1152″ is extended, the platform 1156″ bears against and opens the faceplate 1160″, thereby permitting extension of the platform 1156″ and XeF₂ 1154″ into the cavity 1114″. In other embodiments, the faceplate 1160″ is maintained in a closed position by another means, for example, a mechanism that works in concert and/or interlocks with the mechanism that extends and retracts the module 1152″. Those skilled in the art will understand that other arrangements between the faceplate and sidewall are possible, for example, pivoting around an axis normal to the faceplate and sidewall, or in which the faceplate seals against the outer sidewall of the etching chamber. In other embodiments, the faceplate blocks and exposes the opening in the sidewall by sliding rather than by pivoting. Some embodiments comprise a plurality of faceplates. In some embodiments, the module is installed on the top or bottom of the etching chamber. In some embodiments, the apparatus comprises a plurality of modules.

FIG. 11D illustrates an embodiment comprising a turntable 1070′″ that comprises a plurality of platforms 1156′″ and faceplates 1160′″. The illustrated turntable 1070′″ comprises four platforms 1156′″ and faceplates 1160′″, although those skilled in the art will understand that more or fewer platforms and/or faceplates are possible. Those skilled in the art will also understand that the number of modules and faceplates need not be equal. The turntable is rotatable around an axis 1072′″. In use, a predetermined amount of solid XeF₂ is loaded on one or more of the platforms 1156′″. Rotating the turntable 1070′″ a predetermined angle around the axis 1072′″ moves one of the platforms 1156′″ into the cavity 1114′″ of the etching chamber. In the illustrated embodiment, the faceplate 1160′″ rotates into a position that occludes the opening 1162′″ in the sidewall. The embodiment illustrated in FIG. 11D is useful, for example, in processes that comprise a plurality of etching steps. Those skilled in the art will understand that the embodiments presented above are only exemplary and that any number of mechanisms are useful for moving a solid etchant into the etching chamber.

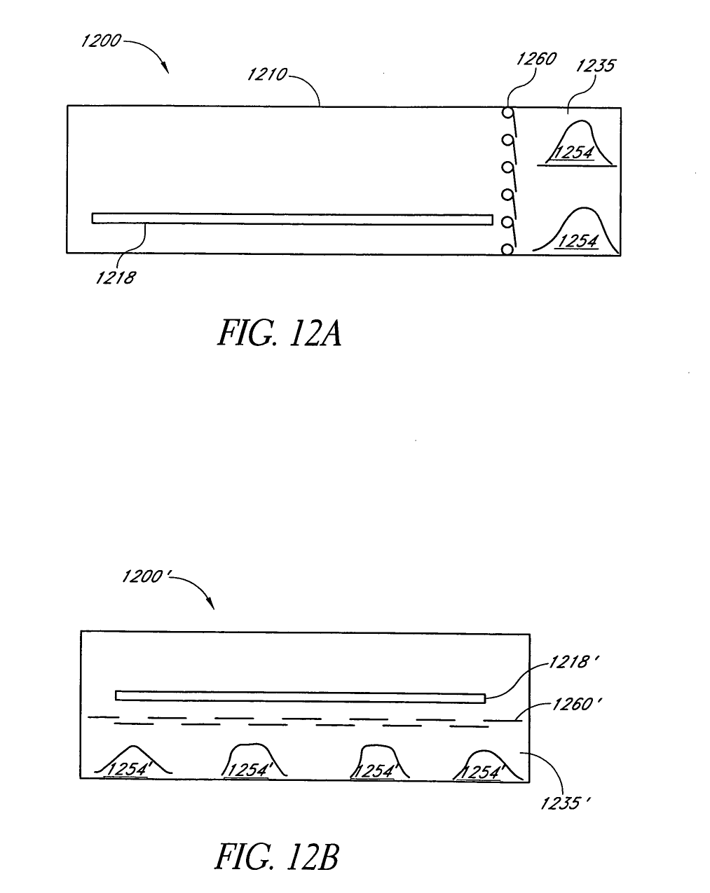

FIG. 12A illustrates in cross section an apparatus 1200 comprising an etching chamber 1210, wherein the etching chamber 1210 comprises a substrate support 1218 and a solid etchant holding area 1235. Solid XeF₂ 1254 is disposed in the solid etchant holding area 1235. Disposed between the substrate support 1218 and the solid etchant holding area 1235 is a configurable partition 1260. In the illustrated embodiment, the partition 1260 comprises a set of louvers. Closing the louvers substantially prevents XeF₂ vapor in the etchant holding area 1235 from reaching the substrate support 1218 and a substrate supported thereon 1216. Opening the louvers permits XeF₂ vapor to etch the substrate 1216. Those skilled in the art will understand that other mechanisms are useful for the configurable partition 1260, for example, one or more shutters, gate valves, tambours and/or roll-tops, and the like. Those skilled in the art will understand that embodiments of the apparatus 1200 include other features described above.

FIG. 12B illustrates an embodiment of an apparatus 1200′ in which the solid etchant holding area 1235′, the configurable partition 1260′, and solid XeF₂ 1254′ are disposed below the substrate support 1218′. In the illustrated embodiment, the configurable partition 1260′ comprises a set of shutters.

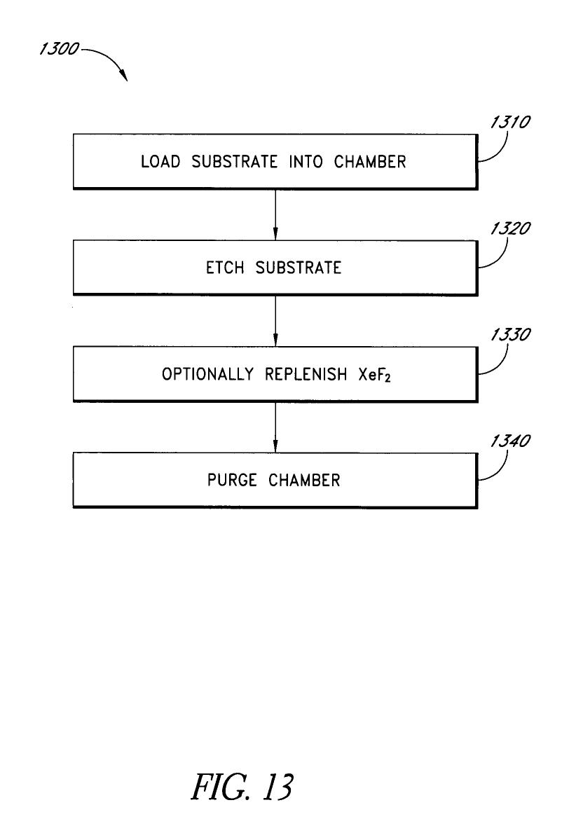

FIG. 13 is a flowchart illustrating an embodiment of a method for processing a substrate with reference to the apparatus illustrated in FIG. 10A-FIG. 10C. Those skilled in the art will understand that other apparatus are also suitable for performing the method, including other apparatus disclosed herein. In step 1310, the substrate 1016 is loaded into the chamber 1010. Optionally, one or more processing steps not using XeF₂ are performed on the substrate 1016 in the etching chamber 1010. The module 1052 is in the retracted position, thereby sealing the XeF₂ 1054 within the inner region 1039 of the access port, and preventing the entry of XeF₂ vapor into the cavity 1014. The particular processing step will depend on the particular device under fabrication, the configuration of the etching chamber 1010, and the particular process flow. An example of a suitable processing step includes depositing a layer or film, for example, a sacrificial layer, a mask, and/or a structural layer, using any method compatible with the configuration of the etching chamber 1010. Examples of suitable methods include spin-coating, sputtering, physical vapor deposition, chemical vapor deposition, atomic layer deposition, molecular beam epitaxy, and the like. Examples of other processing steps include etching using an etchant other than XeF₂, cleaning, and the like.

Step 1320 is an etching step. In step 1320, the XeF₂ module 1052 is extended into the central cavity 1014 of the etching chamber 1010 using the translation device 1036, thereby exposing the substrate 1016 to XeF₂ vapor from the solid XeF₂ 1054. The XeF₂ vapor etches materials and/or structures formed on the substrate 1016, for example, a sacrificial layer in the fabrication of a MEMS device. The module 1052 is then retracted into the access port 1038.

In some embodiments, the material and/or structure is a sacrificial layer used in the fabrication of an interferometric modulator. In some embodiments, the XeF₂ etch comprises a release etch that releases the secondary mirror/conductor 16 as discussed above and illustrated in FIG. 6A. In some embodiments, the XeF₂ vapor etches another material and/or structure used in the fabrication of a MEMS device, for example, an interferometric modulator.

Some embodiments use a predetermined amount of solid XeF₂ 1054 in the etching step. The amount of solid XeF₂ is determined, for example, from the type and amount of material-to-be-etched. For example, in some embodiments, the volume of the sacrificial layer-to-be-removed is known. An amount of solid XeF₂ 1054 is then selected sufficient to etch the sacrificial layer. In other embodiments, the thickness of the sacrificial layer is unknown. In some embodiments, the amount of solid XeF₂ 1054 is selected based on previous experience or on experimentation. In other embodiments, an amount of solid XeF₂ 1054 is selected such that substantially all of the solid XeF₂ sublimes, thereby filling the chamber with XeF₂ vapor at a partial pressure of about 3.8 Torr. Those skilled in the art will understand that amount of solid XeF₂ used in these embodiments depends on a variety of factors including the volume and temperature of the cavity.

In some embodiments, the progress of the release etch is monitored and the etching is terminated at a predetermined endpoint. In some embodiments, the monitoring is performed optically, for example, in the fabrication of an optical modulator. The monitoring is performed using any suitable device. In some embodiments, the monitoring is performed through a window in the etching chamber 1010. In other embodiments, optical sensors are disposed within the etching chamber 1010. In some embodiments, the reflectivity of the substrate is monitored. Those skilled in the art will understand that the reflectivity of the substrate will change as the release etch proceeds in the fabrication of an optical modulator. In some embodiments, the monitoring is performed at one or more wavelengths.

Some embodiments use another type of monitoring, for example, of the concentration of particular compounds in the etching chamber. For example, in some embodiments, the concentration of one or more etching byproducts is monitored. As discussed above, in some embodiments, the etching byproducts include MoF₆ and/or SiF₄. Those skilled in the art will understand that the particular byproducts will depend on factors including the composition of the particular substrate, as well as the materials used in the construction of the etching apparatus 1000. In some embodiments, the etching byproducts are monitored spectroscopically using any method known in the art, for example, using infrared spectroscopy, UV-visible spectroscopy, Raman spectroscopy, and the like. In some preferred embodiments, the etching byproducts are monitored by mass spectroscopy. In some embodiments, the etching byproducts are monitored chromatographically, for example, by gas chromatography, liquid chromatography, and the like. In some embodiments, the disappearance of XeF₂ vapor is monitored, as discussed above for the monitoring of etching byproducts.

In some embodiments, the solid XeF₂ 1054 is monitored, for example, the weight, volume, and/or appearance.

Because XeF₂ is relatively expensive, in some embodiments, an amount of solid XeF₂ 1054 is loaded in the etching chamber such that substantially all of the solid XeF₂ 1054 is exhausted in the etching step 1320. Moreover, unused solid XeF₂ 1054 remaining after completion of the etching step 1320 is likely contaminated with byproducts of the etching process, for example, MoF₆ and/or SiF₄, as well as contaminants entering the etching chamber 1010 in normal use, for example, organic contaminants. Consequently, in some embodiments, solid XeF₂ remaining after step 1320 is not reused.

In some embodiments, for example, where the amount of material-to-be-etched is relatively small, the material-to-be-etched is etched in a single exposure. The XeF₂ module 1052 is extended into the chamber 1010 and remains therein until the XeF₂ vapor etches the material-to-be-etched, for example, one or more sacrificial layers, from the substrate 1016. As described above, in some embodiments, the amount of solid XeF₂ 1054 is predetermined to perform the etch in a single step, and to be substantially exhausted in the etching step 1320. Consequently, no additional portions of solid XeF₂ are added to the module 1052 in the etching of each batch of substrates in these embodiments.

In other embodiments, for example, where amount of material-to-be-etched is relatively large, the method 1300 comprises a plurality of etching steps 1320, each of which comprises an extension of the XeF₂ module 1052 into the central cavity 1014 of the chamber and a retraction of the module 1052 into the access port 1038. In some embodiments, the solid XeF₂ 1054 is not replenished on the module 1052 between etching steps 1320.

In other embodiments, in optional step 1330, the solid XeF₂ 1054 is replenished on the module 1052 between etching steps 1320. In some embodiments, the module 1052 is retracted into the access port 1038 where additional solid XeF₂ 1054 is added to the platform 1056, for example, using door 1050. The module 1052 is then reextended into the central cavity 1014 of the chamber, whereupon additional etching occurs. The etching and replenishment is repeated as needed until the desired degree of etching is achieved. As discussed above, in some embodiments, the total amount of solid XeF₂ is predetermined to reduce waste of XeF₂.

In some embodiments, the etching step 1320 etches one layer from the substrate 1016. In other embodiments, the etching step 1320 etches a plurality of layers from the substrate 1016. For example, some embodiments of the fabrication of the device illustrated in FIG. 6C use a first sacrificial layer between the mirror 14 and 16, and a second sacrificial layer above mirror 14. In some embodiments, the layer or layers comprise substantially one material. In other embodiments, the layer or layers comprise a plurality of materials. In embodiments etching a plurality of layers, in some embodiments, the layers have substantially the same composition. In other embodiments, at least one of the layers has a different composition.

In some embodiments, the amount of solid XeF₂ used in step 1320 controls the degree of etching. Where the quantity of etchable material exceeds the amount of XeF₂, etching proceeds until the XeF₂ is substantially depleted. In some embodiments, this method etches a predetermined thickness of an etchable material.

In step 1340, the chamber 1010 is purged. In some embodiments, the purge removes byproducts of the etching step 1320 from the central cavity 1014 of the etching chamber using the purge system 1020. The particular etching byproducts depend on the particular materials etched in step 1320. In some embodiments, the etching byproduct is MoF₆ and/or SiF₄. With reference to the etching chamber 1010 illustrated in FIG. 10A, some embodiments use a pump/backfill method to purge the cavity 1014. The outlet valve 1034 is opened, thereby fluidly connecting the cavity 1014 of the chamber to the vacuum source. After a predetermined point, for example, time or pressure, the outlet valve 1034 is closed and the inlet valve 1030 opened, thereby filling the cavity 1014 with the purge gas. In some embodiments, the pump/backfill procedure is repeated one or more times. In other embodiments, opening valves 1030 and 1034 causes a purge gas to flow from the source of purge gas 1026 into the etch chamber 1010 through purge inlet 1022, then out of the etch chamber 1010 through the purge outlet 1024 to the vacuum source 1032. Some embodiments do not comprise a vacuum source, and the purge gas is exhausted from the apparatus 1000 through the purge outlet 1024 at substantially ambient pressure. Suitable purge gases are known in the art and are selected based on factors including the particular etching byproduct(s), the process steps preceding and/or following the etching step, the particular process flow, cost of the gas, and the like. Particular examples of purge gases are discussed above. In some embodiments, the chamber 1010 is purged after all of the solid XeF₂ 1054 in the module 1052 has been substantially exhausted.

Some embodiments comprise a single purge step 1340. Other embodiments use a plurality of purge steps. In some embodiments, a plurality of purge steps 1340 are performed after the etching of the substrate is complete. As discussed above, some embodiments comprise a plurality of etching steps 1320. Some of these embodiments comprise at least one purge step 1340 between two etching steps. Some embodiments comprise a purge step 1340 between each etching step. In some embodiments, a purge 1340 is performed substantially contemporaneously with step 1330 in which solid XeF₂ is replenished in the module 1052.

For purposes of illustration, a description of method 1300 with reference to the apparatus in FIG. 12A is as follows. Because the method is substantially as described above, the following description focuses on differences. In optional step 1310, the configurable partition 1260 is closed and the substrate 1216 is subjected to another processing step. In step 1320, the configurable partition 1260 is opened and the substrate 1216 exposed to XeF₂ vapor formed by the solid XeF₂ in the etchant holding area 1235. In optional step 1330, the etchant holding area 1235 is replenished with solid XeF₂. In step 1340, the chamber 1210 is purged.

### EXAMPLE 1

An array of modulators at the stage illustrated in FIG. 7D are fabricated according to the method described in U.S. Published Application 2004/0051929 on a 200-mm diameter glass substrate. The sacrificial layer is molybdenum. The substrate is loaded onto a fused silica substrate support in a stainless steel etching chamber with internal dimensions of 220 mm by 400 mm by 70 mm. The bottom of the etching chamber is equipped with a fused silica window. The etching chamber is also equipped with a port to a mass spectrometric (MS) detector and an etchant unit as illustrated in FIG. 10A-FIG. 10C.

The etching chamber is purged three times by evacuating to 10⁻² torr and backfilling with nitrogen gas at ambient pressure. XeF₂ (8.5 g, 50 mmol) is loaded onto the etchant unit and the unit purged with nitrogen. The module is then extended into the etching chamber. The progress of the etching is monitored optically through the window, as well as using the MS. The etching is complete when color of the substrate changes from grey to uniformly white and the concentration of MoF₆ as detected by the MS levels off.

Those skilled in the art will understand that changes in the apparatus and manufacturing process described above are possible, for example, adding and/or removing components and/or steps, and/or changing their orders. Moreover, the methods, structures, and systems described herein are useful for fabricating other electronic devices, including other types of MEMS devices, for example, other types of optical modulators.

Moreover, while the above detailed description has shown, described, and pointed out novel features of the invention as applied to various embodiments, it will be understood that various omissions, substitutions, and changes in the form and details of the device or process illustrated may be made by those skilled in the art without departing from the spirit of the invention. As will be recognized, the present invention may be embodied within a form that does not provide all of the features and benefits set forth herein, as some features may be used or practiced separately from others.

What is claimed is:

1. An apparatus for etching comprising an etching chamber and a etchant module, wherein
the etchant module is movable between a retracted position and an extended position,
in the retracted position, the etchant module is substantially outside the etching chamber, and
in the extended position the etchant module is substantially within the etching chamber.

2. The apparatus of claim 1, wherein the etching chamber comprises stainless steel.

3. The apparatus of claim 1, further comprising a substrate support.

4. The apparatus of claim 3, further comprising a optical sensor configured to detect the reflectance of a substrate on the substrate support.

5. The apparatus of claim 1, further comprising a faceplate, wherein the faceplate seals the etching chamber from the etchant module when the etchant module is in the retracted position.

6. The apparatus of claim 1, further comprising a purge system.

7. The apparatus of claim 1, wherein the movement of the module between the extended and the retracted position is automated.

8. The apparatus of claim 1, wherein etchant module comprises a platform configured to support solid xenon difluoride.

9. An apparatus for etching comprising:
an etching chamber,
a support for a substrate on which microelectromechanical device is formed,
an etchant module, and
a means for positioning the support and the etchant module in close proximity within the etching chamber.

10. The apparatus of claim 9, wherein the microelectromechanical systems device is an optical modulator.

11. An apparatus for etching comprising a chamber, a support for a substrate on which a microelectromechanical systems device is formed, and solid xenon difluoride, wherein the support and the solid xenon difluoride are disposed within the chamber.

12. The apparatus of claim 11, wherein the microelectromechanical systems device is an optical modulator.

13. An apparatus for etching comprising a support for a substrate on which a microelectromechanical systems device is formed and solid xenon difluoride, wherein the support and the solid xenon difluoride are sufficiently proximate for a vapor formed from the solid xenon difluoride to etch a substrate comprising an etchable material.

14. The apparatus of claim 13, wherein the distance between the support and the solid xenon difluoride is not more than 10 cm.

15. A method for fabricating a microelectromechanical systems device comprising:
disposing within an etching chamber a substrate comprising an etchable material, and
disposing within the etching chamber a solid etchant, wherein the solid etchant forms a gas-phase etchant capable of etching the etchable material.

16. The method of claim 15, wherein the microelectromechanical systems device is an optical modulator.

17. The method of claim 15, wherein the solid etchant is solid xenon difluoride.

18. The method of claim 15, wherein the etchable material comprises molybdenum.

19. The method of claim 15, wherein the etchable material comprises silicon.

20. A method for fabricating a microelectromechanical systems device comprising:
disposing a substrate within an etching chamber;
extending an etchant module into the etching chamber, wherein
a solid etchant is supported on the etchant module, and
the solid etchant forms a gas-phase etchant capable of etching a material on the substrate; and
allowing the gas-phase etchant to etch the material.

21. The method of claim 20, wherein the microelectromechanical systems device is an optical modulator.

22. The method of claim 20, wherein the solid etchant is solid xenon difluoride.

23. The method of claim 20, wherein the material on the substrate comprises molybdenum or silicon.

24. A microelectromechanical systems device fabricated according a method comprising:
disposing within an etching chamber a substrate comprising an etchable material and
disposing within the etching chamber a solid etchant, wherein the solid etchant forms a fluid etchant capable of etching the etchable material.

25. The microelectromechanical systems device of claim 24, wherein the microelectromechanical systems device is an optical modulator.

26. The microelectromechanical systems device of claim 24, wherein the solid etchant is solid xenon difluoride.

27. The microelectromechanical systems device of claim 24, wherein the etchable material comprises molybdenum.

28. The microelectromechanical systems device of claim 24, wherein the etchable material comprises silicon.

29. A method for fabricating a microelectromechanical systems device comprising:
providing solid xenon difluoride within an etch chamber;
supporting a substrate comprising an etchable material within the etch chamber; and
etching the etchable material from the substrate with a vapor generated by the solid xenon difluoride.

30. The method of claim 29, wherein the microelectromechanical systems device is an optical modulator.

31. The method of claim 29, wherein the etchable material comprises molybdenum or silicon.

32. A method for fabricating a microelectromechanical systems device comprising:
supporting a substrate comprising an etchable material within the etch chamber; and
positioning solid xenon difluoride sufficiently proximate to the substrate such that a vapor formed by the solid xenon difluoride etches the etchable material.

33. The method of claim 32, wherein the microelectromechanical systems device is an optical modulator.

34. The method of claim 32, wherein the etchable material comprises molybdenum or silicon.
